(19) United States
(12) Patent Application Publication
(10) Pub. No.: US 2010/0175999 A1
(43) Pub. Date: Jul. 15, 2010

(54) MICROFLUIDIC DEVICE

(76) Inventors: David Barlow, Edinburgh (GB); David Thompson, Edinburgh (GB); Ken MacNamara, Edinburgh (GB); Stuart Polwart, Stirlingshire (GB)

Correspondence Address: KNOBBE MARTENS OLSON & BEAR LLP, 2040 MAIN STREET, FOURTEENTH FLOOR, IRVINE, CA, 92614, US

(21) Appl. No.: 12/523,500

(22) PCT Filed: Jan. 16, 2008
(86) PCT No.: PCT/GB2008/000143

§ 371 Date: Dec. 10, 2009

(30) Foreign Application Priority Data
Jan. 16, 2007 (GB) 0700822.0

(51) Int. Cl. B01L 3/00; B81B 1/00; B81C 1/00; B32B 37/00; B01J 19/00; B01D 57/02

(52) U.S. Cl. 204/600; 422/102; 422/100; 156/182; 422/131

(57) ABSTRACT

The present invention relates to a microfluidic device, comprising a laminate of first and second films, one or each film including an integrally thermoformed structure such that the films together define an enclosed volume (19) for fluid containment therebetween, characterised in that each film itself comprises a laminate of a relatively higher softening temperature thermoplastic polymeric material (14,17) and with respect thereto, a relatively lower melt temperature thermoplastic polymeric material (15,16), the respective relatively low melt temperature thermoplastic polymeric materials of each film being melted together to attach the said first and second films together. The invention further relates to a method of manufacturing the microfluidic device.

The invention relates to a microfluidic device, and a method of forming a said device.

A microfluidic device is a device for manipulating and analysing a fluid sample on a micro-scale. A characterising feature of such devices is the presence of micro-scale volumes (often termed “microstructures”) for holding and conducting fluids for analysis or testing or working on in some manner on the device. The advantages gained by working on such a micro-scale are well known. For the avoidance of doubt, the terms “volume” and “microstructure” as used herein are used to refer to any structure which may be used to for example, contain, manipulate, control or direct the flow of fluids within a microfludic device. Examples of such microstructures are channels, reaction chambers, hybridization chambers, pumps and valves.

A particular form of microfluidic device utilises a substantially planar device format. The development of integrated systems based on such a planar microfluidic device format has been in progress for several decades. They can be used for the automation of research into molecular biology and the development of diagnostic systems. An important milestone with respect to chemical and biochemistry analysis was the publication of the concept of micro-Total Analysis Systems by A. Manz et al (Sensors and Actuators B, 1990, 1, 244-248). The work introduced the concept of integrating all of the required steps of an analytical operation onto a single planar substrate. In this manner all the required processing steps from sample preparation to analysis could be conducted with minimal human intervention. For instance, an entire laboratory's equipment could be miniaturized onto a single device, thereby enabling significant cost and time savings.

Microfluidic devices can be fabricated from a variety of materials involving a range of processing steps. Materials such as glass and silicon are usually structured using semiconductor processing technology. Alternatively, polymer substrates are used to manufacture microfluidic devices. These can be structured with a wide array of technologies, for example, laser micromachining, hot embossing, thermoforming and injection moulding. Polymeric substrates are preferred in many systems over glass or silicon as they enable low cost mass fabrication. An example of a design for the fabrication of microfluidic devices from polymeric substrates is illustrated in U.S. Pat. No. 5,932,799 in which multilayered laminated polyimide films are structured and bonded in an adhesive-less nature. This patent refers to U.S. Pat. No. 5,525,405 which covers the development of polyimide composed of aromatic polyimides with an inorganic bonding enhancer such as Sn such that films can be bonded to form laminates.

An important milestone in the history of microfluidics was the development of entire devices composed of an elastomeric material, poly-di-methyl-siloxane (PDMS) as disclosed in U.S. Pat. No. 6,843,262. These developments were mostly based on pouring an elastomeric resin over microfabricated positive features to create channels in the PDMS.

The various functional requirements for a microfluidic device can be summarized in terms of structural, optical and chemical performance. For example, for use in detection systems using fluorescence-based detection schemes the materials from which the devices are formed should have optical clarity and minimal autofluorescence. In addition, in order to be commercially viable such devices should be susceptible to accurate, automated mass production techniques. Techniques such as thermoforming are useful in this regard, and the wide diversity of available thermoformable polymeric materials makes achieving specific functional requirements more easy. However, it is a general requirement for all such devices that they must have the ability to be accurately structured with microscale fluid containment features. The sizes and shapes of such microstructures are key to the proper performance of these devices and any deviation, even by relatively small tolerances can impair proper functioning or impede it altogether. The use of thermoforming or thermobonding steps in manufacturing subsequent to microstructure formation, which is often a requirement, all too easily causes loss of definition in thermoformed microstructures.

Furthermore, the films, once structured must be stable over time and permit reagents to be stored within the structures without leaching from the polymer, adsorption of reagents, and transmission of gases in order to provide a shelf-life acceptable by the commercial market. It is also desirable that the films are formed from a biocompatible material, so that the reaction to be conducted within the device is not affected, for instance ensuring minimal protein and nucleic acid adsorption to the inside of channels or reaction chambers.

It is an object of the invention to seek to mitigate problems such as these.

According to a first aspect, the invention provides a microfluidic device, comprising a laminate of first and second films, one or each film including a thermo-formed structure such that the films together define an enclosed volume for fluid containment therebetween, characterised in that each film itself comprises a laminate of a relatively higher softening temperature thermoplastic polymeric material with a relatively lower melt temperature thermoplastic polymeric material, the respective relatively lower melt temperature thermoplastic polymeric materials of the films being melted together to attach the said first and second films together. Thus it can be seen that the invention provides a microfluidic device which contains accurately sized and shaped microfluidic structures, which is straightforward and economical to assemble without deformation of the fluid containment volume.

It is preferred that the first film and the second film each comprises a coextruded film. Formation of the microfluidic device from coextruded films of the relatively higher softening temperature and relatively lower melt temperature thermoplastic polymeric materials provides a microfluidic device with a relatively high structural integrity which is straightforward to mass produce.

The relatively lower melt temperature materials of the first film and the second film may each comprise the same material. This ensures that the fluid containment volume has a uniform internal surface. Alternatively, the relatively lower melt temperature materials of the first film and the second film may each comprise different materials, to provide a fluid containment volume with varying internal surface characteristics.

One or each film may further comprise a structural layer disposed on the relatively higher softening temperature material. Preferably, the structural layer comprises a material having a higher melting temperature than the relatively higher softening temperature material. The structural layer provides support to the other materials in the device, and where the films are coextruded, helps keep them flat during coextrusion. It can also assist during thermoforming of the fluid containment volume structure by preventing the relatively higher softening temperature material from sticking to the forming tool, and will also resist melting into imperfections in the tool which may affect optical clarity.

One or each film may further comprise a gas-barrier layer. One or more layers may be combined to provide a tailored gas permeability. Examples of gas barrier materials are EVOH and Polyamide.

In one preferred embodiment, the device may include externally energisable electrodes disposed to be in operative connection with a fluid in the fluid containment volume, the fluid containment volume comprising an electrophoresis vessel. Preferably, the device will further comprise a reaction-mixture holding vessel.

It is preferred that one or both films are optically clear, and that the relatively lower melt temperature material comprises a biocompatible, physiologically inert material.

One or each film may also comprise a liquid barrier layer for enhancing the self-life and performance of pre-packaged reagents. One or more layers may be combined to provide a tailored moisture permeability. COC is an example of a liquid barrier.

The relatively higher softening temperature material of the first and/or second film preferably comprises a cyclic olefin copolymer, a polycarbonate, a polyester, a polymethyl methacrylate, a polyamide or blends or copolymers thereof. The relatively lower melt temperature material preferably comprises polyethylene.

According to a second aspect, the invention provides a method of manufacturing a microfluidic device, the device comprising a laminate of first and second films, one or each film including a thermo-formed structure such that the films together define an enclosed volume for fluid containment therebetween, characterised by the steps of providing first and second films, each film itself comprising a laminate of a relatively higher softening temperature thermoplastic polymeric material with a relatively lower melt temperature thermoplastic polymeric material and combining said first and second films together by melting the relatively lower melt temperature materials together, characterised in that the melting step is performed at a lower temperature than the softening temperature of the relatively high softening temperature thermoplastic polymeric materials. Thus, the method ensures that the integrity of the thermo-formed fluid containment structure is not affected by the process for attachment of the films.

It is preferred that the method includes the step of forming the said first and second films by coextrusion of the relatively higher softening temperature and relatively lower melt temperature materials prior to thermoforming the fluid containment structure and melting together of the films.

The method may further include the step of coextruding one or more further material with each film, such as a support layer, a gas barrier layer or a liquid barrier layer.

The method may further include the step of forming externally energisable electrodes disposed to be in operative connection with a fluid in the reaction volume.

The first and second thermoplastic films may be formed by coextrusion with the heat seal layer on one side and a support layer on the other and the method further include the step of forming the thermoformed reaction volume by (vacuum) forming in a tool with the support layer in contact with the tool surface. The reaction volume forming step is preferably a thermo-forming step, carried out at a lower temperature than the melting temperature of the support layer.

The first and second films may be formed by coextrusion of a cyclic olefin copolymer with polyethylene, polymethyl methacrylate (PMMA), polyamides (PA) and blends of copolymers thereof.

The invention will now be illustrated by way of example with reference to the following drawings in which:

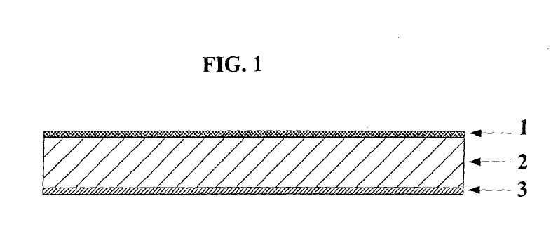

FIG. 1 shows a first embodiment of a film according to the invention;

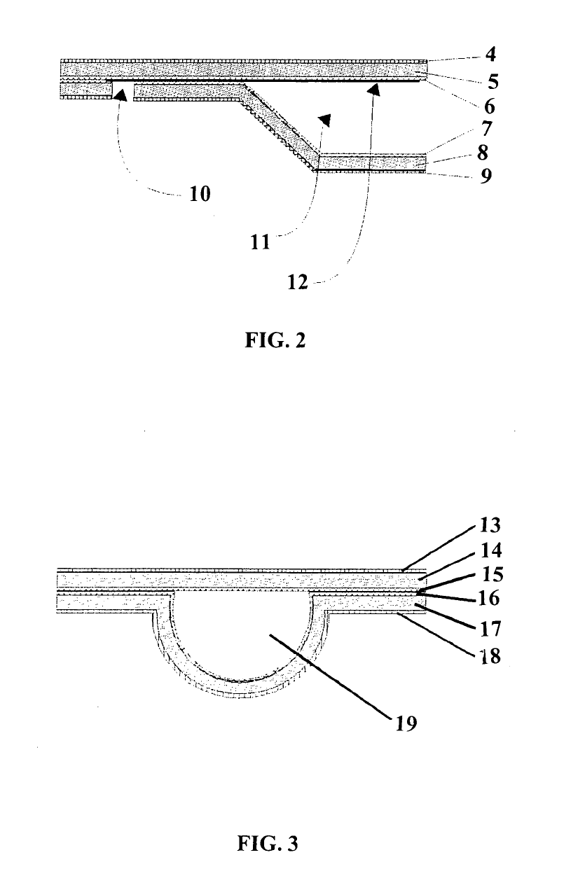

FIG. 2 shows a second embodiment of a film according to the invention;

FIG. 3 shows a third embodiment of a film according to the invention;

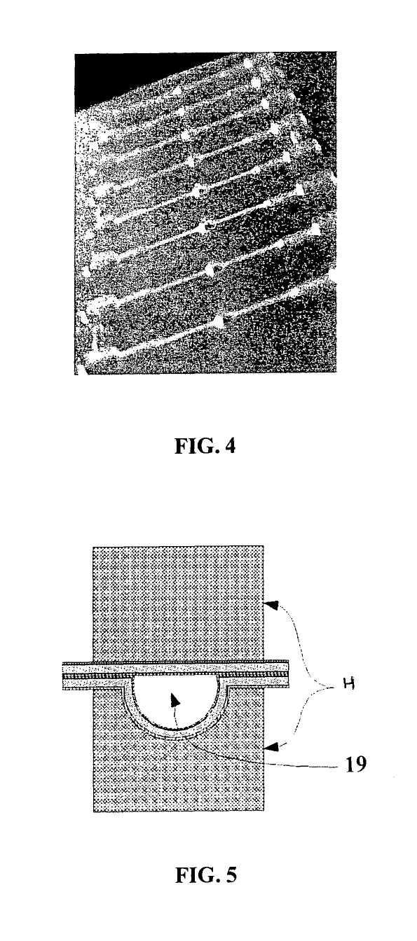

FIG. 4 is a photograph of the film of FIG. 3;

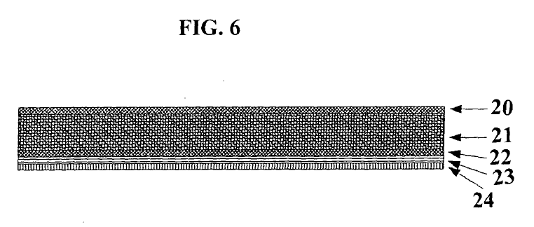

FIG. 5 shows a film of FIG. 3 with a heater;

FIG. 6 shows a fourth embodiment of a film according to the invention;

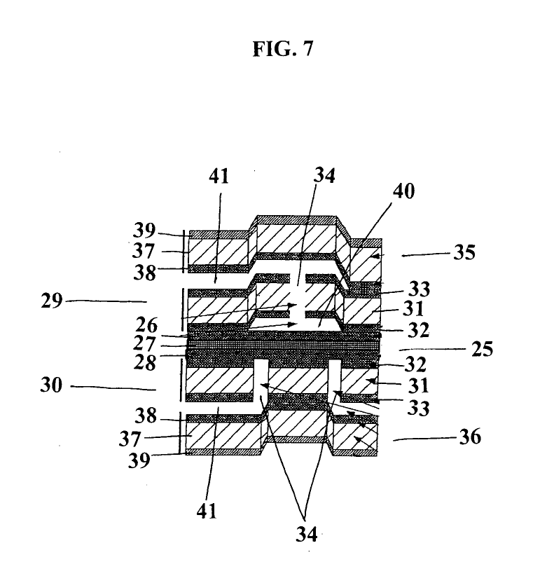

FIG. 7 shows a fifth embodiment of a film according to the invention;

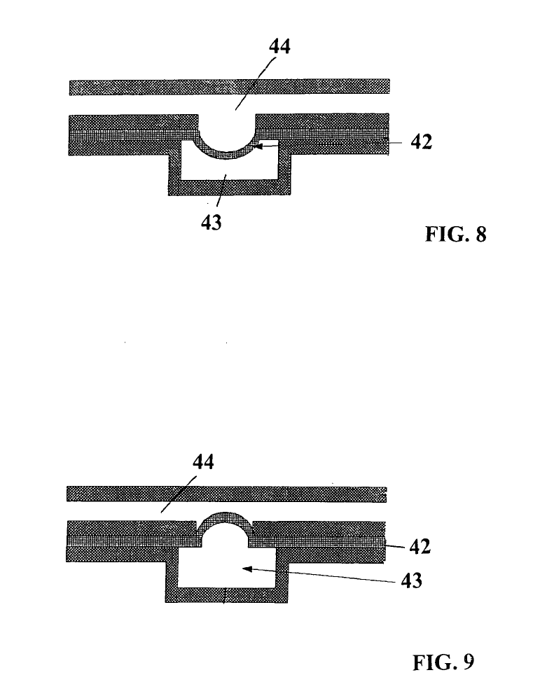

FIG. 8 shows a sixth embodiment of a film according to the invention in a first position;

FIG. 9 shows the film of FIG. 8 in a second position;

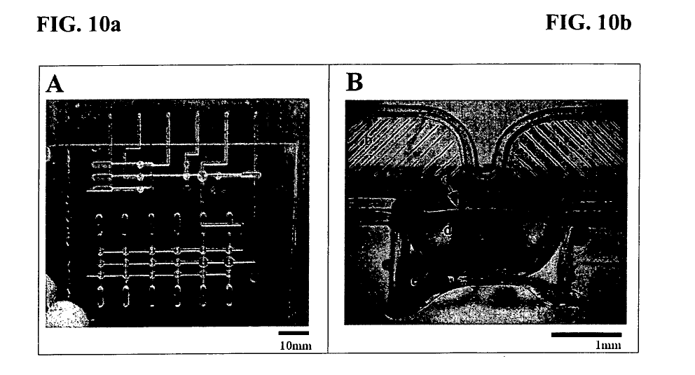

FIG. 10a is a plan view photograph of a seventh embodiment of a film according to the invention; and

FIG. 10b is a cross section along a-a of the film of FIG. 10a.

The film shown in FIG. 1 is a co-extruded unit comprising three layers 1, 2, 3. The first layer 1 is made from a polyethylene, Exact 0210 from DEX Plastics (Heerlenm, the Netherlands). The second layer 2 is made from a blend of COC, Topaz from Ticona. The blend is 70% Topaz 6013 and 30% Topaz 8007. The third layer 3 is made from a polypropylene, HP420M from Basell (Hoofdorp, The Netherlands). Extrusion may be carried out by any known process therefor.

The second layer 2 is sandwiched between the two outer layers 1, 3 and may be formed by extrusion as a thin layer. The outer layers 1, 3 allow the film to be more robust and avoid breakage of thin layer 2. The film was made by co-extruding the three layers. The extruder was programmed to obtain a total film thickness of 160 μm with the center core of COC having a thickness of 130 μm.

After co-extrusion, the film may be thermoformed to provide one or more microstructures (not shown). The microstructures may be conventional microstructures such as channels, reaction chambers, hybridization chambers, pumps and valves, or may be specially developed for use with the film of the present invention. The microstructures which are selected for any particular film will depend on the application of that film.

One application of the film of FIG. 1 is for manufacturing a microfluidic device for use in DNA analysis. For such an application, the film may include a microstructure which consists of a channel with a buffer chamber at either end. Within the buffer chambers are planar electrodes used to separate the DNA with an electrophoresis step. The electrodes are carbon electrodes which are screen printed onto the polyethylene layer (the melt seal layer). In the context the invention, platinum and silver electrode may also be used, for example Ag/AgCl may be used as a reference electrode and Pt as a counter electrode.

Electrodes must be encapsulated while being exposed at one point externally and at another point internally. By applying an electrode to a melt seal layer it becomes possible to laminate the melt seal layer to another layer or unit including a channel so that the electrode is exposed internally on one side. A hole may then be punched through the melt seal layer on the other side of the electrode so that the electrode is also exposed externally. Screen printed carbon electrodes can easily break upon application of heat and pressure during lamination of the films to form the microfluidic device, but this may be avoided by using a co-extruded film having an appropriate thickness of polyethylene and by using an appropriate pressure, temperature, and time for lamination. These variables combined enable the film to be laminated while ensuring that the polyethylene does not flow sufficiently to break the screen printed electrodes.

FIG. 2 is used to describe the concept of inserting electrodes into the multilayer device. The device comprises polypropylene layer 4, COC layer 5, polyethylene layer 6, polyethylene layer 7, COC layer 8 and polypropylene layer 9. Area 10 is the hole to allow access to the electrode which is thereby accessible externally. Area 11 is a buffer chamber or some internal lumen where voltage is to be applied and finally area 12 is the electrode itself. The electrode may be applied by printing, and may consist of a printable conductive material. Such materials are carbon, graphite, and metallic based inks.

Another application of the film of FIG. 1 is for manufacturing a microfluidic device for use in a nucleic acid amplification reaction such as the Polymerase Chain Reaction (PCR). For such an application the film may include microstructures which consist of 1.5 μl reaction chambers. In addition, the specific design of the co-extruded polymer was stable for the high temperature requirements of PCR, whilst maintaining good lamination. Furthermore, the thin film enabled rapid heat transfer which is very important for conducting the reaction as fast as possible. The film properties enables the laminate to be slightly flexible which permitted a very tight fit between the reaction chamber and the heater, thereby facilitating rapid heat transfer. Finally, the selection of COC as the bulk layer and its excellent optical properties enables quantification with real-time PCR techniques commonly employed on much larger volumes. It should also be noted that reagents used in PCR can absorb certain polymers and it is therefore important to control the surface properties to improve the reaction yield or even to attain a successful reaction, as explained for example in Liu et al., Lab on Chip, 2006, 769-775.

The PCR reaction can be conducted by thermo-cycling with any number of methods. These include but are not limited to thermoelectric heaters, water baths of varying temperatures, thin film heating elements, Infra-red based heating, continuous flow designs and hot air designs. The method of heating can be changed to suit the exact application, but often the basis of the design is to permit rapid heat transfer.

The PCR reaction chamber was thermoformed using a hemispherical female tool with two channels. One channel was used for loading the reaction chamber with pre-mixed PCR reagents. The other channel was used as an air vent. The tape was then thermo-cycled and following this the PCR reagents were withdrawn and run on a electrophoresis gel for analysis of the PCR amplicons.

FIG. 3 illustrates a third embodiment, in which the device comprises polypropylene layer core polymer layer 14 (in this embodiment COC), polyethylene melt seal layers 15 and 16, bulk layer 17 with the formed channels and reaction chambers, polypropylene layer 18 and finally a hemispherical reaction chamber 19. FIG. 4 is a photograph of the hemispherical reaction chambers of FIG. 3 comprising two channels and loading chambers formed in the co-extruded films. FIG. 5 shows the PCR reaction chamber 19 with the heater H used to conduct the thermo-cycling.

The film shown in FIG. 6 is a co-extruded unit comprising five layers 20, 21, 22, 23, 24. The first layer 20 is 15 μm thick, and is made from a polyethylene, Exact 0210, from DEX Plastics (Heerlenm, The Netherlands). The second layer 21 is 100 μm thick, and is made from the same blend of the COC, Topaz COC, as in the embodiment of FIG. 1. The third layer 22 is made from a blend of 80% Exact 0210 and 20% Bynel 47E710, a maleic anhydride grafted polyethylene from Dupont. The fourth layer 23 is 15 μm thick and is made from an ethylene vinyl alcohol (EVOH) Kurraray LCF101 from Mutsui. The fifth layer 24 is 15 μm thick and is made from a maleic anhydride grafted polypropylene 18707 from Arkema.

The film was made by co-extruding the five layers. Layer 23 acts as a gas barrier. Layer 22 acts as a tie layer to tie layer 23 to layer 21.

The film shown in FIG. 7 comprises a number of individual co-extruded units, which have been laminated together to form a larger more complex fluid control structure. The core elastomer unit 25 comprises three layers 26, 27, 28. The two outer layers 26, 28 are both made of a polyethylene, Exact 0210, from DEX Plastomers (Heerlen, The Netherlands). The central layer 27 is made of an elastomer, Adflex X100F, from Basell (Hoofddorp, The Netherlands). The three extrusion lines are run at appropriate speeds to produce a central layer 27 approximately 30 μm thick with 3.75 μm thick outer layers 26, 28.

Two units 29, 30, each consisting of a layer 31 of COC co-extruded between two layers 32, 33 of the polyethylene, Exact 0210, are laminated to either side of the core elastomer unit 25. Each unit 29, 30 contains one or more microstructures in the form of vials 34 which extend through the entire unit 29, 30.

Two further units 35, 36, each consisting of a layer 37 of COC co-extruded between a layer 38 of the polyethylene, Exact 0210 and a layer 39 of polypropylene, are laminated to either side of the two units 29, 30, and form the outermost units. Layers 31 and 37 are generally about 130 μm thick, layers 32, 33, 38, 39, each 15 μm thick.

Three of the units 29, 35, 36 are shaped by thermoforming before lamination to provide a number of microstructures in the form of void areas 40 and channels 41 between the units.

Lamination is conducted in such a manner that the units are bonded across the entire surface except in the area between and directly proximal to the vials 34, void areas 40 and channels 41. The outer units 35, 20 are elevated above their melting temperature so that the polyethylene layer 38 of each outer unit bonds with the adjacent polyethylene layer 32 of the inner units 29, 30. The core elastomer unit 25 remains substantially firm and thus maintains its integrity so that the polyethylene layers 26, 28 on the elastomer unit 25 do not flow into the microstructures 18, 23, 24 adjacent to the elastomer unit 25.

By applying pressure or a vacuum on either side of the elastomer unit 25, fluid flow through the film may be controlled, for example, the movement upward of elastomer unit 25 (by negative pressure) can allow a fluid in lower channel 41 to pass through vials 34 thereby acting as a valve.

This is illustrated by the film shown in FIGS. 8 and 9 which comprised layer 42, made of an elastomer, Adflex X100F, from Basell (Hoofddorp, The Netherlands). In addition, the density of molecules at the surface of the elastomer layer may be altered, which has applications in controlling reactions and enhancing the signal to noise ratio.

On one side of the elastomer layer 42 is a void area 43. On the other side of the elastomer layer 42 is a T-shaped channel 44, which contains biomolecules to be analysed with a surface bound reaction. When a vacuum is applied to the void area 43, the elastomer layer 42 deforms into the void area 43 as shown in FIG. 8. This changes the density of biomolecules on the surface. This can be used to control the hybridization of nucleic acids, or to control antigen-antibody interactions or biotin-streptavidin complex formation. It can also enhance signal to noise ratio as it reduces the area under investigation and so concentrates the signal. When pressure is applied to the void area 43, the elastomer layer 42 deforms into the T-shaped channel 44. This results in a larger surface area which will be better at binding the biomolecules in solution.

Finally, FIG. 10a is a plan view of a device according to the present invention and a-a represents the position of the cross section as shown in FIG. 10b. The device comprises microfluidic channel b (hatched area), flexible polymer film c, metering chamber d and pneumatic control chamber e. It is pointed out that the circles in FIG. 10b are merely voids generated in microscopy preparation.

1. A micro fluidic device, comprising a laminate of first and second films, one or each film including an integrally thermoformed structure such that the films together define an enclosed volume for fluid containment there between, characterized in that each film itself comprises a laminate of a relatively higher softening temperature thermoplastic polymeric material and with respect thereto, a relatively lower melt temperature thermoplastic polymeric material, the respective relatively low melt temperature thermoplastic polymeric materials of each film being melted together to attach the said first and second films together.

2. The device according to claim 1, wherein the first film and second film are each coextruded films.

3. The device according to claim 1, wherein the first film or the second film includes externally energisable electrodes disposed to be in operative connection with a fluid in the reaction volume.

4. The device according to claim 1, wherein the melting temperatures of all layers can withstand the upper temperature used in a PCR thermo-cycling reaction process and that the relatively higher melt temperature layer will remain substantially rigid under these conditions.

5. The device according to claim 4, wherein each first relatively higher melt temperature material is substantially rigid at temperatures from 10 to 50° C.

6. The device according to claim 1, wherein one or both films comprise an optically clear material.

7. The device according to claim 1, wherein the heat seal layer material comprises a biocompatible, physiologically inert material.

8. The device according to claim 1, wherein the heat seal layer material coats at least a part of an internal surface of the integrally-formed reaction volume.

9. The device according to claim 1, wherein the heat seal layer material coats substantially the entire internal surface of the integrally-formed reaction volume.

10. The device according to claim 1, wherein the relatively low melting point materials of the first film and the second film comprise the same material.

11. The device according to claim 1, wherein the relatively low melting point materials of the first film and the second film comprise different materials.

12. The device according to claim 1, wherein the integrally-formed reaction vessel comprises an electrophoresis vessel.

13. The device according to claim 12, further comprising a reaction-mixture holding vessel.

14. The device according to claim 1, further comprising a structural layer disposed on the relatively high melting point material of the first and/or second film.

15. The device according to claim 14, wherein the structural layer comprises a material having a higher melting temperature than the relatively high melting point material.

16. The device according to claim 1, further comprising a gas-barrier layer.

17. The device according to claim 1, further comprising a liquid-barrier layer.

18. The device according to claim 1, wherein the relatively high melting point material of the first and/or second film comprises a cyclic olefin copolymer, a polycarbonate, a polyester, a polymethyl methacrylate, a polyamide or blends or copolymers thereof.

19. The device according to claim 1, wherein the melt seal layer comprises polyethylene.

20. The device according to claim 19, wherein the heat seal layer comprises corona-treated polyethylene.

21. The device according to claim 1, wherein one or both films comprise an elastomer layer.

22. The device according to claim 21, wherein the elastomer layer is sandwiched between two melt seal layers to form an elastomer unit.

23. The device according to claim 22, wherein the elastomer unit is sandwiched between two co-extruded units, the co-extruded units comprising a bulk layer sandwiched between two melt seal layers.

24. The device according to claim 21, wherein one or both films comprise a void area or channel on either side of the elastomer layer or unit.

25. A method of manufacturing a microfluidic device, the device comprising a laminate of first and second films, one or each film including a thermo-formed structure such that the films together define an enclosed volume for fluid containment there between, characterized by the steps of providing first and second films, each film itself comprising a laminate of a relatively high softening temperature thermoplastic polymeric material and with respect thereto, a relatively lower melt temperature thermoplastic polymeric material and combining said first and second films together by melting the relatively lower melt temperature materials together, characterized in that the melting step is performed at a lower temperature than the softening temperature of the relatively high softening temperature thermoplastic polymeric materials.

26. The method according to claim 25, wherein the first and second thermoplastic films are formed by coextrusion of a relatively higher softening point thermoplastic polymeric material and relatively lower melting point thermoplastic polymeric material, prior to formation of the reaction volume.

27. The method according to claim 25, further including the step of forming externally energisable electrodes disposed to be in operative connection with a fluid in the reaction volume.

28. The method according to claim 26, wherein the first and second thermoplastic films are formed by coextrusion with the heat seal layer on one side and a support layer on the other, the method further including the step of forming the thermoformed reaction volume by forming in a tool with the support layer in contact with the tool surface.

29. The method according to claim 28, wherein the reaction volume forming step is a thermo-forming step, carried out at a lower temperature than the melting temperature of the support layer.

30. The method according to claim 26, wherein the first and second films are formed by coextrusion of a cyclic olefin copolymer with polyethylene.
